(19) United States
(12) Patent Application Publication
(10) Pub. No.: US 2015/0279619 A1
(43) Pub. Date: Oct. 1, 2015

(54) Substrate Tray and Substrate Processing Apparatus Including Same

(71) Applicant: JUSUNG ENGINEERING CO., LTD., Gwangju-si, Gyeonggi-do (KR)

(72) Inventors: Sung Woo Cho, Daegu (KR); Jong In Kim, Gwangju-si (KR); Ja Il Park, Daejeon (KR); Ki Chul Lee, Gwangju-si (KR); Jong-Yong Choi, Yongin-si (KR)

(73) Assignee: Jusung Engineering Co., Ltd., Gwangju-si (KR)

(21) Appl. No.: 14/435,428

(22) PCT Filed: Nov. 5, 2013
(86) PCT No.: PCT/KR2013/009927

§ 371 Date: Apr. 13, 2015

(30) Foreign Application Priority Data
Nov. 7, 2012 (KR) 10-2012-0125342

(51) Int. Cl. H01J 37/32; C23C 16/458; C23C 16/50; H01L 21/687

(52) U.S. Cl. CPC H01J 37/32009; H01L 21/68771; H01L 21/68785; C23C 16/458; C23C 16/50; H01J 37/32715

(57) ABSTRACT

Disclosed is a substrate tray which facilitates to realize a large size, and to prevent defects caused by sagging, and a substrate processing apparatus comprising the same, wherein the substrate tray may include a plurality of straps for supporting a plurality of substrates arranged in a first axis direction; and a support frame connected with the straps in a second axis direction being perpendicular to the first axis direction, wherein a length in each of the straps is larger than a length of the substrate with respect to the second axis direction.

### CROSS REFERENCE TO RELATED APPLICATIONS

This application claims the benefit of the Korean Patent Application No. 10-2012-0125342 filed on Nov. 7, 2012, which is hereby incorporated by reference as if fully set forth herein.

### BACKGROUND

1. Field of the Invention

The present invention relates to a substrate tray for loading a substrate, and a substrate processing apparatus comprising the same.

2. Discussion of the Related Art

A substrate processing apparatus is configured to carry out a texturing process for etching a substrate, a process for forming a semiconductor layer, and a process for forming an electrode. This substrate processing apparatus carries out the above-mentioned processes by the use of substrate tray capable of loading a plurality of substrates. For example, a substrate processing apparatus for carrying out a thin film deposition process (for example, plasma deposition process) may simultaneously deposit a thin film material on a plurality of substrates loaded at fixed intervals onto a substrate tray.

FIG. 1 schematically illustrates a related art substrate tray.

Referring to FIG. 1, the related art substrate tray 10 may include a support frame 11 and a support plate 12. The support frame 11 is formed in a rectangular frame, and the support frame 11 is combined with the margin of the support plate 112, to thereby form an external edge of the substrate tray 10. The support plate 12 is formed in a plate shape, and is combined with the support frame 11. On the support plate 12, there are a plurality of substrates (S) loaded at fixed intervals.

The related art substrate tray 10 has the following problems.

First, in order to realize the large-sized substrate tray 10, it is necessary to increase a size of the support plate 12 onto which the plurality of substrates (S) are loaded. However, if the support plate 12 of one structure is increased in size, the material used to manufacture the support plate 12 is consumed excessively so that a manufacturing cost of the support plate 12 is increased. Furthermore, it inevitably requires to increase a size of an apparatus for manufacturing the support plate 12. In this respect, it has limitations on increasing the size of the support plate 12.

Also, as the support plate 12 is manufactured in the large size, a weight of the support plate 12 is also increased. In addition, according as the number of substrates (S) loaded onto the support plate 12 is increased, a total weight of the substrates (S) is also increased. When the margin of the support plate 12 is combined with the support frame 11, a central portion of the support plate 12, which is apart from the support frame 11, may sag by the increased weight of support plate 12 and substrates (S). Accordingly, misalignment of the substrate (S) might occur inside the substrate processing apparatus, thereby causing defects such as pick-up failure of the substrate (S) and non-uniformity of process.

### SUMMARY

Accordingly, the present invention is directed to a substrate tray and a substrate processing apparatus comprising the same that substantially obviates one or more problems due to limitations and disadvantages of the related art.

An aspect of the present invention is to provide a substrate tray which facilitates to realize a large size, and to prevent defects caused by sagging, and a substrate processing apparatus comprising the same.

Additional advantages and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these and other advantages and in accordance with the purpose of the invention, as embodied and broadly described herein, there is provided a substrate tray that may include a plurality of straps for supporting a plurality of substrates arranged in a first axis direction; and a support frame connected with the straps in a second axis direction being perpendicular to the first axis direction, wherein a length in each of the straps is larger than a length of the substrate with respect to the second axis direction.

In another aspect of the present invention, there is provided a substrate processing apparatus that may include a process chamber for providing a process space; a susceptor movably provided in the process chamber; and a substrate tray loaded into the process space and supported by the susceptor, wherein the substrate tray includes a plurality of straps for supporting a plurality of substrates arranged in a first axis direction; and a support frame connected with the plurality of straps in a second axis direction being perpendicular to the first axis direction, wherein a length of each of the straps is larger than a length of the substrate with respect to the second axis direction.

In another aspect of the present invention, there is provided a substrate processing apparatus that may include a process chamber for providing a process space; a susceptor movably provided in the process chamber; and a substrate tray loaded into the process space and supported by the susceptor, wherein the substrate tray includes a plurality of straps for supporting a plurality of substrates arranged in a first axis direction; and a support frame connected with the plurality of straps in a second axis direction being perpendicular to the first axis direction, wherein a length of each of the straps is the same a length of the substrate with respect to the second axis direction.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 schematically illustrates a related art substrate tray;

FIG. 2 illustrates a substrate tray according to the present invention;

FIG. 3 is an exploded perspective view illustrating a support frame of the substrate tray shown in FIG. 2;

FIGS. 4 to 6 illustrate various embodiments of protrusions in a strap;

FIG. 7 illustrates another embodiment of a strap;

FIGS. 8 to 11 illustrate various embodiments of tension maintaining unit and connection portion;

FIG. 12 illustrates an operation of the tension maintaining unit;

FIG. 13 illustrates one embodiment of mounting unit and fixing portion;

FIG. 14 is a cross sectional view illustrating the mounting unit of FIG. 13

FIG. 15 illustrates another embodiment of mounting unit and fixing portion;

FIG. 16 is a cross sectional view illustrating a second mounting unit of FIG. 15; and

FIGS. 17 and 18 illustrates a substrate processing apparatus according to the present invention.

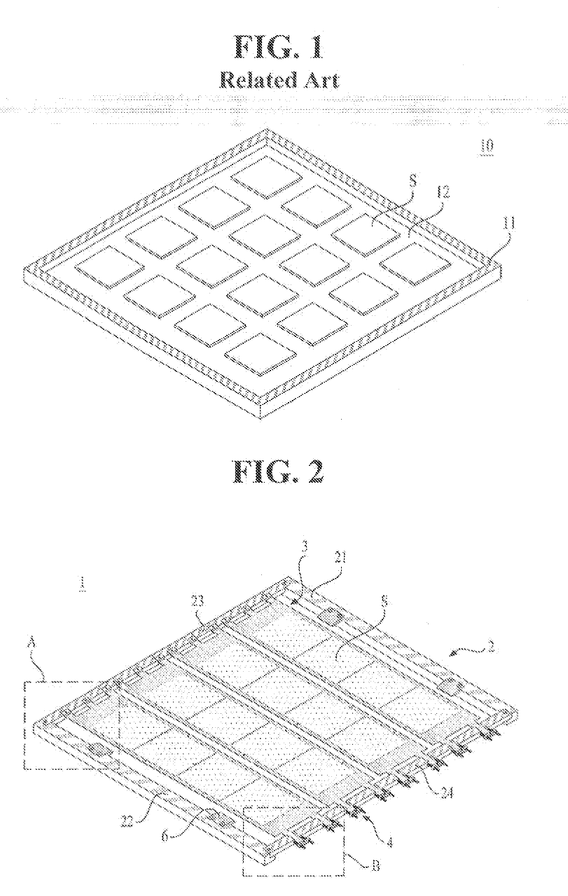

### DETAILED DESCRIPTION OF THE INVENTION

Reference will now be made in detail to the exemplary embodiments of the present invention, examples of which are illustrated in the accompanying drawings. Wherever possible, the same reference numbers will be used throughout the drawings to refer to the same or like parts.

Hereinafter, a substrate tray according to the present invention will be described with reference to the accompanying drawings.

The substrate tray 1 according to the present invention carries out a process for supporting and loading a plurality of substrate (S) to be treated into the inside of a substrate processing apparatus. Herein, the substrate (S) may be treated with a substrate processing, for example, deposition process, etching process, cleaning process, and etc.

Referring to FIG. 2, the substrate tray 1 according to the present invention may include a plurality of straps 3 for supporting the plurality of substrates (S) arranged in a first axis direction (X-axis direction), and a support frame 2 combined with the plurality of straps 3 in a second axis direction (Y-axis direction) being perpendicular to the first axis direction (X-axis direction). With respect to the second axis direction (Y-axis direction), a length of each straps 3 is relatively larger than a length of the substrate (S).

The strap 3 supports the plurality of substrates (S). The strap 3 supports the plurality of substrates (S) arranged in the first axis direction (X-axis direction). That is, the plurality of substrates (S) are arranged in the first axis direction (X-axis direction) on the strap 3, and are supported by the strap 3.

Each of the straps 3 is formed in a band shape having a small width. In each of the straps 3, a length of the first axis direction (X-axis direction) is larger than a length of the second axis direction (Y-axis direction).

With respect to the second axis direction (Y-axis direction), a length of each strap 3 is larger than a length of the substrate (S). In the second axis direction (Y-axis direction), the length in the plurality of straps 3 is larger in comparison to the length of the substrate (S). That is, a width in the plurality of straps 3 is larger than a width of the substrate (S). Accordingly, an entire rear surface of the substrate (S) is brought into contact with the plurality of straps 3. That is, the rear surface of the substrate (S) has no area which is not in contact with the plurality of straps 3.

The support frame 2 may be combined with the plurality of straps 3. While the plurality of straps 3 are arranged along the second axis direction (Y-axis direction), the plurality of straps 3 are combined with the support frame 2. The support frame 2 is formed in a rectangular frame shape with an opening. The plurality of straps 3 are arranged in the opening of the support frame 2. Eventually, the support frame 2 supports the plurality of straps 3, and simultaneously forms an outer edge of the substrate tray 1.

The substrate tray 1 according to the present invention may have the following effects.

Firstly, in order to increase the entire size of the substrate tray 1 according to the present invention, the number of straps 3 is increased, instead of increasing the size in each of the straps 3. For obtaining the increased size of the substrate tray 1 according to the present invention, the number of straps 3 is increased without additionally manufacturing a large-sized strap 3. That is, the straps 3 are additionally arranged along the second axis direction (Y-axis direction) so as to increase the entire size of the substrate tray 1. Accordingly, it facilitates to increase the size of the substrate tray 1 according to the present invention. The large-sized substrate tray 1 according to the present invention enables to carry out the substrate processing for the increased number of substrates (S), and furthermore to improve the yield for substrate (S).

Secondly, even though the number of straps 3 is increased so as to increase the size of the substrate tray 1 according to the present invention, the size in each of the straps 3 is identically maintained so that a weight in each of the straps 3 is not increased. Thus, it is possible to prevent each of the straps 3 from sagging due to its own weight, to thereby prevent defects such as pick-up failure and non-uniformity of process, and furthermore to improve the yield for substrate (S).

Thirdly, the rear surface of the substrate (S) is brought into contact with all the plurality of straps 3 so that it is possible to prevent a reaction material from being permeated through the gap between each of the straps 3 and reacting to the rear surface of the substrate (S). That is, it is possible to prevent the reaction material from reacting to the other portions except a predetermined portion of the substrate (S) to be treated by the process. Accordingly, it is possible to minimize consumption of the reaction material, and to improve process efficiency for the substrate (S) by preventing the reaction to the other portions except the predetermined portion of the substrate (S) to be treated by the process.

Fourthly, the rear surface of the substrate (S) is brought into contact with all the plurality of straps 3 so that it is possible to constantly maintain a thermal conductivity on the entire substrate (S). That is, heat transmitted to the substrate (S) is constantly maintained for the process so that it is prevent discoloration on the substrate (S) even after the process, to thereby improve quality of the substrate (S).

Hereinafter, the support frame 2 and the plurality of straps 3 according to the embodiments of the present invention will be described in detail with reference to the accompanying drawings.

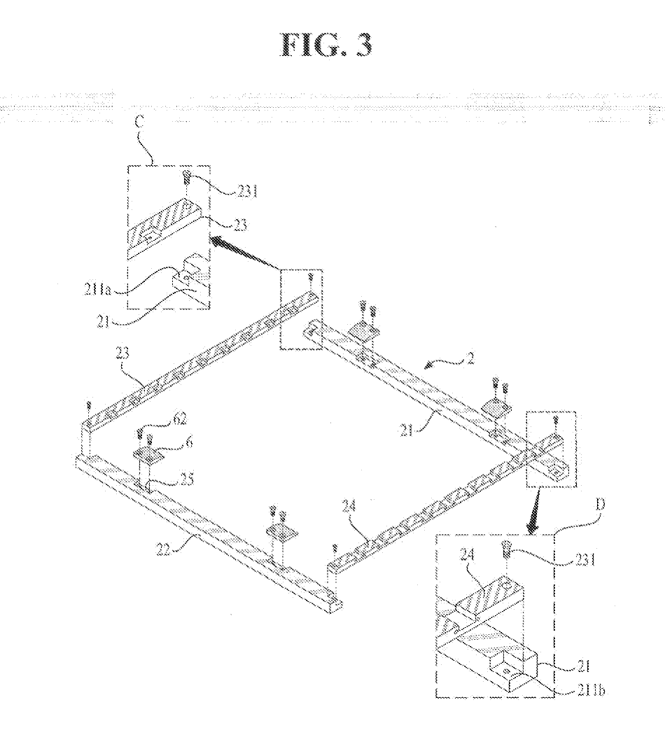

Referring to FIGS. 2 and 3, the support frame 2 is formed in the rectangular frame shape with the opening, to thereby support the plurality of straps 3. To this end, the support frame 2 may include first to fourth frame members 21, 22, 23 and 24.

The first frame member 21 and the second frame member 22 are arranged in parallel, and provided at a predetermined interval from each other with the plurality of straps 3 provided in-between. As each of the first frame member 21 and the second frame member 22 is transferred inside the substrate processing apparatus by the use of tray transfer means (not shown), each of the first frame member 21 and the second frame member 22 is formed of a metal material to prevent abrasion in accordance with a contact with the tray transfer means, that is, tray transfer roller. For example, each of the first frame member 21 and the second frame member 22 may be formed of an aluminum material or a metal material including the aluminum material.

The third frame member 23 and the fourth frame member 24 are combined with both ends of the first frame member 21 and the second frame member 22. Accordingly, the support frame 2 is formed in the rectangular frame shape by the mutual combinations of the first and second frame members 21 and 22 and the third and fourth frame members 23 and 24. The third frame member 23 and the fourth frame member 24 may be formed of a ceramic material or a non-metal material including the ceramic material.

Both ends of the third frame member 23, as shown in ‘C’ portion of FIG. 3, are respectively inserted into and combined with a first groove 211a prepared at a corner of one end in each of the first and second frame members 21 and 22 by the use of fastening member 231. In this case, the fastening member 213 may be screw or bolt with disk-shaped head.

Both ends of the fourth frame member 24, as shown in ‘D’ portion of FIG. 3, are respectively inserted into and combined with a second groove 211b prepared at a corner of the other end in each of the first and second frame member 21 and 22 by the use of fastening member 231. In this case, the fastening member 213 may be screw or bolt with disk-shaped head.

Referring to FIG. 2, the plurality of straps 3 are provided at fixed intervals in the support frame 2, to thereby support the plurality of substrates (S). The plurality of straps 3 are arranged at fixed intervals along the second axis direction (Y-axis direction). The plurality of straps 3 respectively support the plurality of substrates (S). The plurality of straps 3 are formed in a band shape with a predetermined width and length, and are combined with the third and fourth frame members 23 and 24. In the drawings, there are the four straps 3, but not limited to four. That is, the number of straps 3 may be larger or smaller than four.

The plurality of straps 3 are provided at fixed intervals, and are arranged along the second axis direction (Y-axis direction). When carrying out the substrate processing for the substrate (S), the plurality of straps 3 may be heated and thus expanded in the second axis direction (Y-axis direction). Thus, the plurality of straps 3 are provided at fixed intervals along the second axis direction (Y-axis direction).

The plurality of straps 3 are formed of a metal material with low thermal expansion coefficient and high thermal conductivity. For example, the plurality of straps 3 may be formed of any one of aluminum material, Inconel-based alloy material, Hastelloy material, Hastelloy-based alloy material, and metal material such as Hastelloy material coated with aluminum.

Each of the plurality of straps 3 supports the plurality of substrates (S). The plurality of substrate (S) are provided in each of the straps 3, and are arranged along the first axis direction (X-axis direction). In the drawings, the four substrates (S) are supported by each strap 3, but not limited to four. The number of substrates (S) supported by each strap 3 may be larger or smaller than four.

If the substrate (S) supported by the plurality of straps 3 is formed in a regular tetragon shape, a width or length of the substrate (S) is smaller than a length of the second axis direction (Y-axis direction) of the strap 3. That is, the length of the second axis direction (Y-axis direction) of the strap 3 corresponds to a width of the strap 3, whereby the width of the strap 3 is larger than the width or length of the substrate (S).

If the substrate (S) supported by the plurality of straps 3 is formed in a rectangular shape, the substrate (S) has a long side and a short side. Firstly, if the long side of the substrate (S) is provided in parallel to the first axis direction (X-axis direction), and the short side of the substrate (S) is provided in parallel to the second axis direction (Y-axis direction), a width of the strap 3 is larger than the short side of the substrate (S). Secondly, if the short side of the substrate (S) is provided in parallel to the first axis direction (X-axis direction), and the long side of the substrate (S) is provided in parallel to the second axis direction (Y-axis direction), a width of the strap 3 is larger than the long side of the substrate (S). Eventually, regardless of the short side or long side of the substrate (S), a length of each of the straps 3 is larger than a length of the substrate (S) supported by the plurality of straps 3 with respect to the second axis direction (Y-axis direction).

If forming the length of each of the straps 3, the entire rear surface of the substrate (S) is brought into contact with the straps 3.

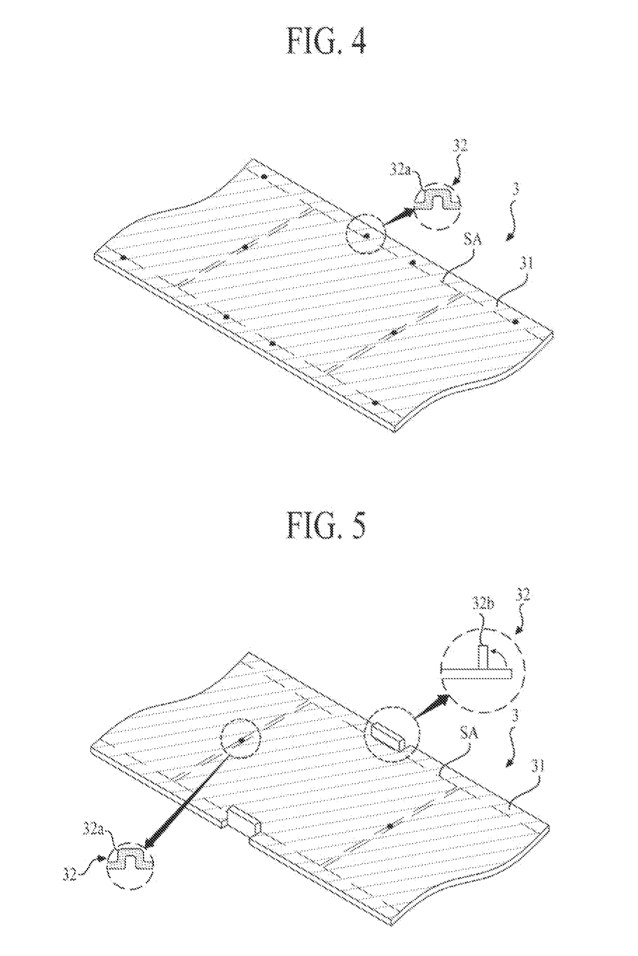

Referring to FIGS. 2 and 4, each of the straps 3 may include a support surface 31 by which the plurality of substrates (S) are supported. That is, the plurality of substrates (S) may be supported by the support surfaces 31 of the respective straps 3. The plurality of substrates (S) are arranged along the first axis direction (X-axis direction) on the support surfaces 31 of the respective straps 3.

An area of the support surface 31, onto which each of the substrates (S) is arranged, is defined as a support area (SA). The support area (SA) may be formed in a shape corresponding to a shape of the substrate (S). As shown in the drawings, each of the plurality of substrates (S) supported by the support surface 31 has the regular tetragon shape, whereby the support area (SA) has the regular tetragon shape corresponding to that of the substrate (S).

The plurality of straps 3 may include a plurality of protrusions 32. The plurality of protrusions 32 enable to position the plurality of substrates (S), supported on the support surface 31, be positioned on the respective support areas (SA).

The plurality of protrusions 32 upwardly protrude from the support surface 31. That is, the protrusion 32 is formed by the upwardly-protruding support surface 31. The protrusion 32 is formed in the outside of each side in each support area (SA). The plurality of protrusions 32 may be provided along each side of the support area (SA), or may be provided at a predetermined interval from each side of the support area (SA). That is, if the plurality of substrates (S) are supported by the support surface 31, the plurality of protrusions 32 may be brought into contact with each side in each of the substrates (S), or may be provided at a predetermined interval from each side in each of the substrates (S).

The protrusion 32 is formed on the support surface 31, and is positioned in the circumference of the support area (SA). If the plurality of substrates (S) are supported by the strap 3, the protrusion 32 guides the plurality of substrates (S) so that the plurality of substrates (S) are positioned in the respective support areas (SA). Furthermore, when the substrate tray 1 is loaded into the substrate processing apparatus 100, the protrusion 32 prevents the plurality of substrates (S) from being detached from the respective support areas (SA). If any one of the substrates (S) is detached from the support area (SA), it is difficult to completely carry out the reaction for the plurality of substrates (S), thereby lowering the process efficiency for the substrate (S). Also, when the substrate tray 1 is unloaded from the substrate processing apparatus 100, the protrusion 32a prevents the plurality of substrates (S) from being detached from the straps 3, that is, prevents the plurality of fixed substrates (S) from being detached from the straps 3 and being damaged.

The plurality of protrusions 32 may be formed by punching, wherein each protrusion 32 protruding from the support surface 31 in each of the straps 3 may have ∩-shaped cross section. The protrusion 32 formed by punching is referred to as the first protrusion 32a. The plurality of first protrusions 32a may be formed in all four sides of the support area (SA). As shown in the drawings, one of the first protrusion 32a may be formed in each of the two confronting sides in the first axis direction (X-axis direction), whereby two of the first protrusion 32 may be totally formed in the two confronting sides of the first axis direction (X-axis direction). Also, two of the first protrusion 32a may be formed in each of the two confronting sides in the second axis direction (Y-axis direction), whereby four of the first protrusion 32 may be totally formed in the two confronting sides of the second axis direction (Y-axis direction). However, the number of the first protrusions 32a may be larger or smaller than the above-described number.

Referring to FIG. 5, there is provided another example showing the plurality of protrusions 32. If forming the protrusions 32 in the two confronting sides of the second axis direction (Y-axis direction) in the plurality of straps 3 by punching, the following problems may occur. If the protrusion 32 is formed by punching, the inside of the support area (SA) may be inclined due to the small space between the side of the support area (SA) and the side of the strap 3. Thus, the plurality of substrates (S) supported by the support area (SA) are not in contact with the support surface 31 of the strap 3, whereby the gap may occur between the substrate (S) and the support surface 31. In this case, the reaction material may permeate through the gap, and then react to the rear surface of the substrate (S), to thereby lower the process efficiency of substrate (S).

After cutting some parts of the two confronting sides of the second axis direction (Y-axis direction) in the plurality of straps 3, the cut parts are upwardly curved so that the protrusion 32 is formed, which is referred to as the second protrusion 32b. In this case, some part of the strap 3 is cut and upwardly curved so that the second protrusion 32b protrudes from the support surface 31. In this case, even though the second protrusion 32b is formed, it is possible to prevent the support area (SA) from being inclined. Also, even though there is the small space between the side of the support area (SA) and the side of the strap 3, the second protrusion 32b is easily formed by adjusting the cutting degree of the strap 3.

Even when forming the second protrusion 32b in the two confronting sides of the second axis direction (Y-axis direction), the first protrusion 32a is formed in the two confronting sides of the first axis direction (X-axis direction) of the support area (SA) by punching. This is because there is a difficulty in performing the cutting process for forming the protrusion 32 in the two confronting sides of the first axis direction (X-axis direction).

Herein, one of the second protrusion 32b is formed in each of the two confronting sides of the second axis direction (Y-axis direction), and one of the first protrusion 32a is formed in each of the two confronting sides of the first axis direction (X-axis direction). However, the number of first protrusion 32a or second protrusion 32b for each side may be more than one.

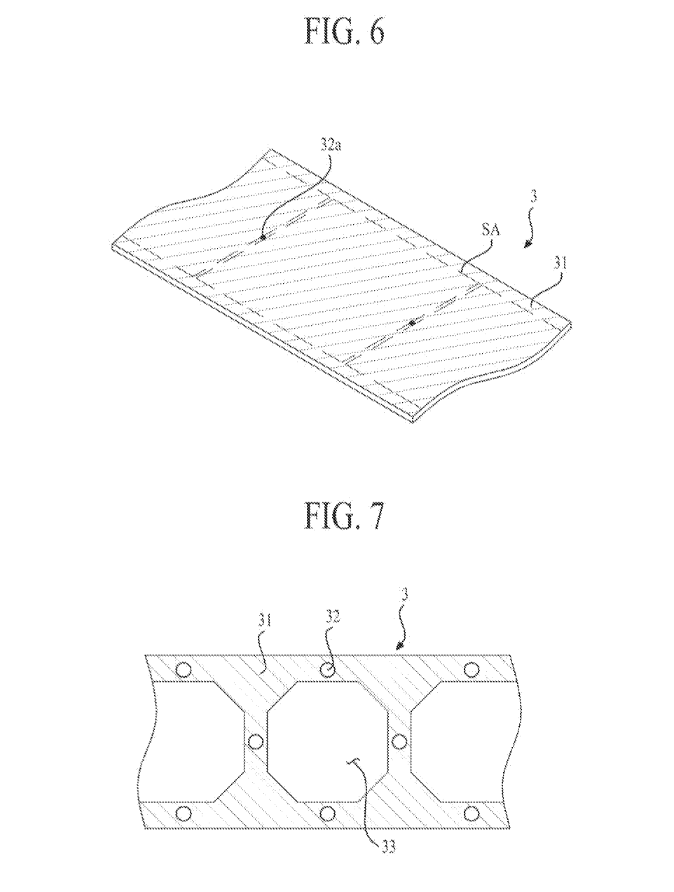

Referring to FIG. 6, there is another example showing the plurality of protrusions 32.

According to the embodiment of the present invention, the first protrusion 32a is formed in the two confronting sides of the first axis direction (X-axis direction) of the support area (SA) by punching. However, it is possible to omit the protrusion 32a or 32b from the two confronting sides of the second axis direction (Y-axis direction).

When the substrate tray 1 is loaded into the substrate processing apparatus 100, or unloaded from the substrate processing apparatus 100, the substrate tray 1 moves along the first axis direction (X-axis direction). That is, the plurality of substrates (S) supported by the plurality of straps 3 move in the first axis direction (X-axis direction) in accordance with the movement of the substrate tray 1, whereby there is a high possibility of detachment from the support area (SA). Thus, the first protrusion 32a is formed adjacent to the two confronting sides of the first axis direction (X-axis direction) of the support area (SA), whereby it is possible to achieve an object of the first protrusion 32a while the plurality of substrates (S) are guided.

Referring to FIG. 7, each of the straps 3 may include a transmitting portion 3 penetrating therethrough. The transmitting portion 33 enables to easily transmit heat to the plurality of substrates (S) supported by the plurality of straps 3. The transmitting portion 33 penetrates through the strap 3. That is, the transmitting portion 33 is formed by partially opening the support surface 31 of the strap 3.

A size of the transmitting portion 33 is smaller than a size of each of the substrates 3. Thus, even though the reaction material permeates through the gap between the two neighboring straps 3 during the process for the substrate (S), it is possible to minimize a contact between the reaction material and the rear surface of the substrate (S).

The transmitting portion 33 enables to directly transmit heat to the plurality of substrates (S), to thereby improve the process efficiency of substrate (S).

Also, the transmitting portion 33 minimizes a contact between the strap 3 and the substrate (S), and maximizes an exposure of the rear surface of the substrate (S). That is, the transmitting portion 33 is formed in a predetermined size which is smaller than the size of the substrate (S), wherein the predetermined size of the transmitting portion 33 is determined at its maximum size within a range capable of supporting the substrate (S). Preferably, the size of transmitting portion 33 is determined within a range capable of supporting the other portions of the substrate (S) except the corresponding portions of the substrate (S) to be treated with the process, and exposing the corresponding portions of the substrate (S) to be treated with the process. In this case, the corresponding portions of the substrate (S) to be treated with the process are not brought into contact with the strap 3, to thereby prevent discoloration of the substrate (S).

The transmitting portion 33 transmits heat to the substrate (S), and furthermore prevents byproducts between the reaction material and the substrate (S) from remaining on the strap 3 during the process for the substrate (S). After the reaction between the substrate (S) and the reaction material is completed, the byproducts such as powder may be generated. If the other substrate (S) is supported by the strap 3 on which the byproducts remain, the other substrate (S) may be affected by the byproducts. That is, heat is not transmitted to the substrate (S) if the byproducts remain between the strap 3 and the substrate (S), to thereby lower the process efficiency of substrate (S). However, owing to the transmitting portion 33 penetrating through the strap 3, it is possible to prevent the byproducts from remaining on the strap 3, to thereby overcome the above-mentioned problem.

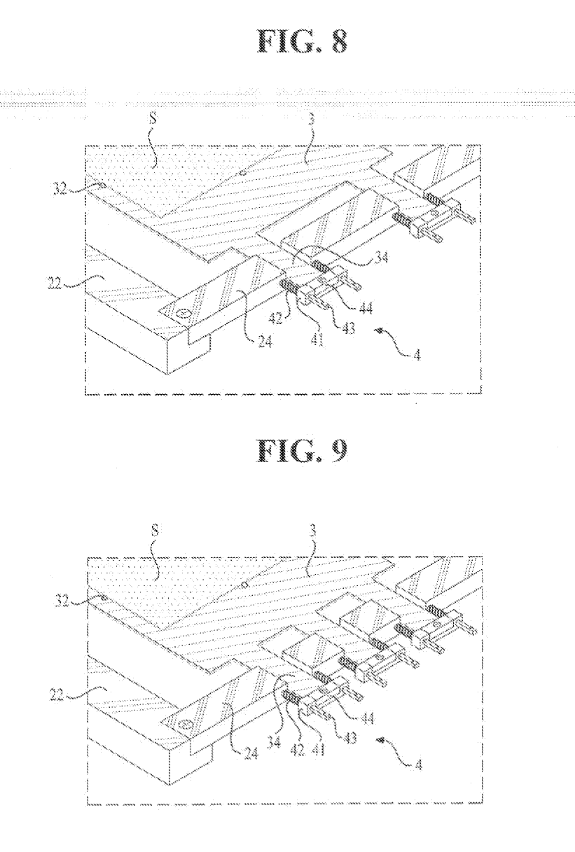

Referring to FIGS. 2 and 8, the substrate tray 1 according to the present invention may include a plurality of tension maintaining units 4 for maintaining a tension in each of the straps 3. The tension maintaining unit 4 is connected with each of the straps 3, to thereby maintain the tension in each of the straps 3. The tension maintaining unit 4 maintains the tension in each of the straps 3, and prevents each strap 3 from sagging by its own weight and the weight of plurality of substrates (S) supported by each strap 3.

The tension maintaining unit 4, which is provided outside the support frame 2, constantly maintains the tension in each of the straps 3. The tension maintaining unit 4 may be connected with an end of each of the straps 3 at the outside the support frame 2.

Each of the straps 3 may include a connection portion 34 being connected with the tension maintaining unit 4. The connection portion 34 may be the end of each of the straps 3. That is, a width of the connection portion 34 may be the same as a width of the support surface 31. That is, a length of the support surface 31 in the second axis direction (Y-axis direction) may be the same as a length of the connection portion 34 in the second axis direction (Y-axis direction).

In consideration of a size of the tension maintaining unit 4, if a width of the support surface 31 is the same as a width of the connection portion 34, an interval between the adjacent two straps 3 becomes larger. If the interval between the adjacent two straps 3 becomes larger, the number of straps 3 provided inside the substrate tray 1 of the same size is decreased so that the number of substrates (S) supported by the straps 3 is also decreased. That is, the number of substrates (S) to be treated by one process is decreased so that the yield for substrate (S) is lowered.

Accordingly, it is preferable that the width of connection portion 34 be smaller than the width of the support surface 31. That is, there is a width difference between the support surface 31 and the connection portion 34.

If one tension maintaining unit 4 is provided in each of the straps 3, one tension maintaining unit 4 is insufficient to stably maintain the tension in each of the straps 3. Thus, each of the straps 3 may include the plurality of connection portions 34 diverged from each strap 3. The plurality of connection portions 34 extend in the first axis direction (X-axis direction) from the end of each of the straps 3. Each of the connection portions 34 is connected with the tension maintaining unit 4.

The plurality of connection portions 34 are diverged from each of the straps 3, wherein a width in each of the connection portions 34 is smaller than a width of the strap 3. In consideration of a width of the tension maintaining unit 4, the plurality of connection portions 34 are positioned adjacent to the center of the support surface 31 instead of the two confronting sides in the second axis direction (Y-axis direction) of the support surface 31. That is, the plurality of connection portions 34 are positioned in such a manner that a height difference is provided between the outer side of the second axis direction (Y-axis direction) and the outer side of the support surface 31.

Referring to FIGS. 2 and 8, the tension maintaining unit 4 may include a sliding bracket 41 connected with the connection portion 34, and an elastic member 42 positioned between the sliding bracket 41 and the support frame 2. The tension maintaining unit 4 may include a guide pin 43 for guiding the movement of the sliding bracket 41, and simultaneously maintaining the position of the elastic member 42. The tension maintaining unit 4 may include a fixing block 44 connected with the sliding bracket 41 so as to connect the connection portion 34 and the sliding bracket 41 with each other.

Also, one tension maintaining unit 4 may include the plurality of guide pins 43. The guide pin 43 may be arranged adjacent to the connection portion 34. The guide pin 43 may be provided at the outer side of the support frame 2. The guide pin 43 is provided in the fourth frame member 24 of the support frame 2, and is formed in a direction from the center of the support frame 2 toward the first axis direction (X-axis direction). That is, the guide pin 43 is provided in the fourth frame member 24 in parallel to the connection portion 34.

The sliding bracket 41 is connected with the guide pin 43 and the connection portion 34. The sliding bracket 41 is arranged in parallel to the fourth frame member 24. That is, the sliding bracket 41 extends in the second axis direction (Y-axis direction). The sliding bracket 41 is movably provided in the guide pin 43. To this end, the sliding bracket 41 has a hole into which the guide pin 43 is fixedly inserted. A shape of the hole included in the sliding bracket 41 corresponds to a shape of the guide pin 43.

The sliding bracket 41 is connected with the connection portion 34 by the use of fixing block 44. The sliding bracket 41 may have a groove into which the fixing block 44 is fixedly inserted. The fixing block 44 is inserted into the groove of the sliding bracket 41, and is connected with the sliding bracket 41. The connection portion 34 is positioned between the fixing block 44 and the sliding bracket 41, and the connection portion 34 is connected with the sliding bracket 41 by the connection between the fixing block 44 and the sliding bracket 41. That is, when the fixing block 44 is connected with the sliding bracket 41, a pressure is applied to the connection portion 34, whereby the connection portion 34 is connected with the sliding bracket 41.

The elastic member 42 is arranged between the fourth frame member 24 and the sliding bracket 41, to thereby cover the guide pin 43. One side of the elastic member 42 is brought into contact with the fourth frame member 24, and the other side of the elastic member 41 is brought into contact with the sliding bracket 41. Under the circumstance that the elastic member 42 is compressed by a predetermined power, the elastic member 42 is arranged between the fourth frame member 24 and the sliding bracket 41. That is, the fourth frame member 24 and the sliding bracket 41 are pushed away from each other in the first axis direction (X-axis direction). Eventually, the pressure is applied to the sliding bracket 41, which is movably provided in the guide pin 43 by the elastic member 42, so that the sliding bracket 41 is positioned in the direction to be apart from the fourth frame member 24 along the first axis direction (X-axis direction). According as the pressure is applied to the sliding bracket 41 by the elastic member 42, the connection portion 34 connected with the sliding bracket 41 and the strap 3 including the connection portion 34 are pulled to the direction being apart from the fourth frame member 24.

Referring to FIG. 8, the two connection portion 34 according to the first embodiment of the present invention are diverged from the strap 3. Also, the tension maintaining unit 4 according to the first embodiment of the present invention is connected with each of the diverged connection portions 34. That is, two of the tension maintaining unit 4 are connected with one of the strap 3.

Each connection portion 34 is provided with one pair of guide pins 43 and one pair of elastic members 42. Also, the sliding bracket 41 is connected with each of the connection portions 34.

Referring to FIG. 9, the three connection portion 34 according to the second embodiment of the present invention are diverged from the strap 3. Also, the tension maintaining unit 4 according to the second embodiment of the present invention is connected with each of the diverged connection portions 34. That is, three of the tension maintaining unit 4 are connected with one of the strap 3.

According as one strap 3 is connected with the three tension maintaining units 4, it is possible to stably maintain the tension of the strap 3 by the three tension maintaining units 4.

According to the above first and second embodiments of the present invention, the number of connection portions 34 and the number of tension maintaining units 4 may be two or three, but not limited to these numbers. That is, the number of connection portions 34 and the number of tension maintaining units 4 may be larger than the above-described number.

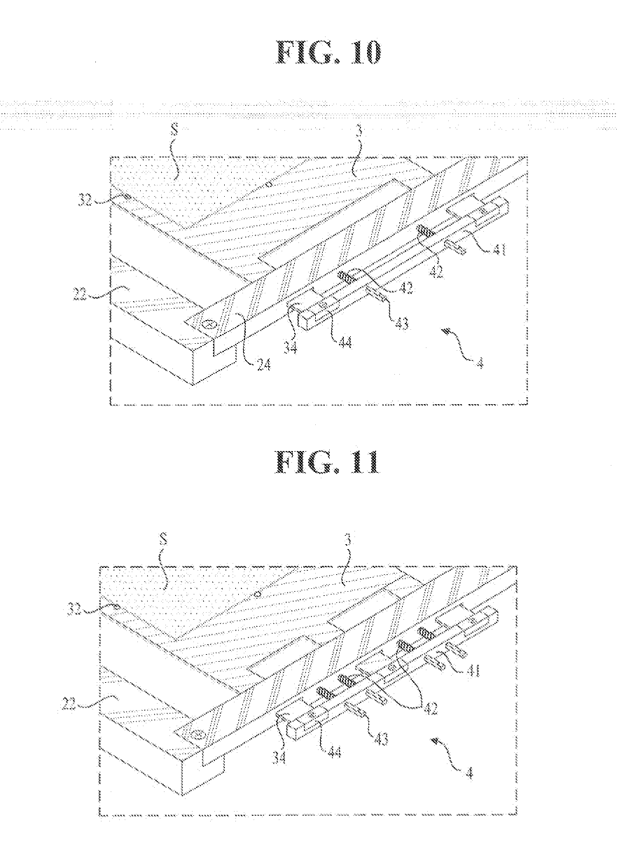

Referring to FIG. 10, the two connection portions 34 according to the third embodiment of the present invention are diverged from the strap 3. The tension maintaining unit 4 according to the third embodiment of the present invention is connected with the two connection portions 34 in common. That is, one tension maintaining unit 4 is connected with one strap 3.

The tension maintaining unit 4 may include one pair of elastic members 42 and one pair of guide pins 43.

Herein, one pair of elastic member 42 and one pair of guide pins 43 are arranged between two of the connection portions 34. The sliding bracket 41 is connected with the two connection portions 34. The tension maintaining unit 4 according to the third embodiment of the present invention may include two fixing blocks 44 so as to connect the two connection portions 34 with the sliding bracket 41.

Referring to FIG. 11, the three connection portions 34 according to the fourth embodiment of the present invention are diverged from the strap 3. The tension maintaining unit 4 according to the fourth embodiment of the present invention is connected with the three connection portion 34 in common. That is, one strap 3 is connected with one tension maintaining unit 4.

The tension maintaining unit 4 may include two pairs of elastic members 42 and two pairs of guide pins 43. One pair of elastic member 42 and one pair of guide pins 43 are provided between the two adjacent connection members 34, to thereby provide the two pairs of elastic members 42 and the two pairs of guide pins 43.

The sliding bracket 41 is connected with the three connection portions 34. Also, there are provided the three fixing blocks 44 which correspond to the number of connection portions 34.

Hereinafter, an operation of the tension maintaining unit 4 will be described in detail with the accompanying drawings.

Referring to FIG. 12, the elastic member 42 of the tension maintaining unit 4 pushes the sliding bracket 31 and the connection portion 34 and the strap 3 fixed to the sliding bracket 41 through the use of elasticity, so that the sliding bracket 41 and the strap 3 are pushed to be away from the fourth frame member 24.

As shown in the upper drawing of FIG. 12, even though the connection portion 34 and the strap 3 are pushed by the elastic member 42, the strap 3 is maintained in its original length due to the material properties.

However, if the plurality of substrates (S) are supported by the strap 3, and the strap 3 is heated by the heat of the process for the substrate (S), the strap 3 is increased in its length. On assumption that there is no tension maintaining unit 4, if both ends of the strap 3 are fixed to the support frame 2, the center of the strap 3 may sag due to gravity. However, the tension maintaining unit 4 pulls the connection portion 34 and the strap 3 to the direction being away from the fourth frame member 24. Thus, even though the strap 3 is increased in its length, the elastic member 42 is restored to its original shape, whereby the connection portion 34 and the strap 3 are pushed to the direction being away from the fourth frame member 42 by the increased length of the strap 3. Accordingly, the strap 3 is tensely maintained without sagging. As shown in the lower drawing of FIG. 12, an arrow indicates the increased length of the strap 3.

When the strap 3 is not heated any more after completion of the process for the substrate (S), and the plurality of substrates (S) are removed from the strap 3, the strap 3 is restored to its original length. In this case, since restoring force of the strap 3 is larger than elastic force of the elastic member 42, as shown in the upper drawing of FIG. 12, the elastic member 42 is restored to a compression state.

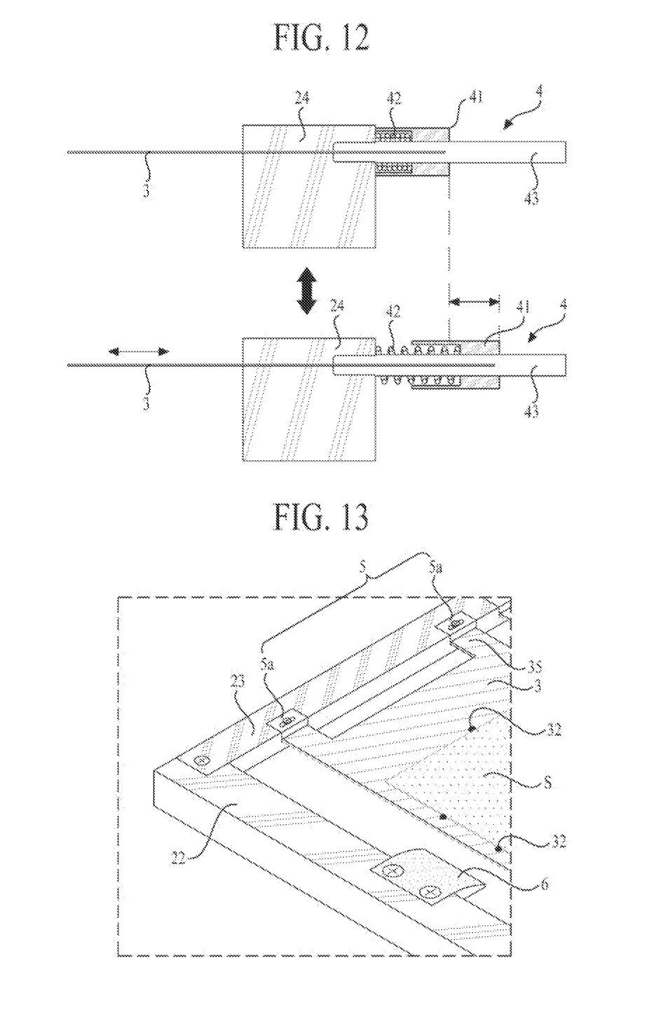

Referring to FIG. 13, the substrate tray 1 according to the present invention may include at least one mounting unit 5 for mounting the plurality of straps 3 on the support frame 2. In each of the plurality of straps 3, the mounting unit 5 is connected with an opposite side to the side connected with the tension maintaining unit 4.

The plurality of straps 3 may include the fixing portion 35 formed in the opposite side of the connection portion 34 with respect to the support surface 31. That is, the connection portion 34 is formed at one end of each of the straps 3, and the fixing portion 35 is formed at the other end of each of the straps 3.

The fixing portion 35 may be formed by diverging the end of each of the straps 3. Thus, a width of the fixing portion 35 is smaller than a width of the support surface 31. That is, with respect to the second axis direction (Y-axis direction) a length of the fixing portion 35 is smaller than a length of the support surface 31. However, the width of the fixing portion 35 may be the same as the width of the support surface 31. Since the end of the strap 3 is fixed by the mounting unit 5, the fixing portion 35 formed by diverging the end of the strap 3 is described simply.

The end of each of the straps 3 is diverged into the two fixing portions 35. Each of the two fixing portions 35 is connected with the mounting unit 5.

According as the fixing portion 35 is arranged between the third frame member 23 and the mounting unit 5, and the third frame member 23 of the support frame 2 is connected with the mounting unit 5, the fixing portion 35 is mounted on the support frame 2. The third frame member 23 may be provided with a groove for the mounting unit 5.

One end of each of the straps 3 is pulled by the tension maintaining unit 4, and the other end of each of the straps 3 is fixed by the use of mounting unit 5, whereby it is possible to maintain the tension in the plurality of straps 3.

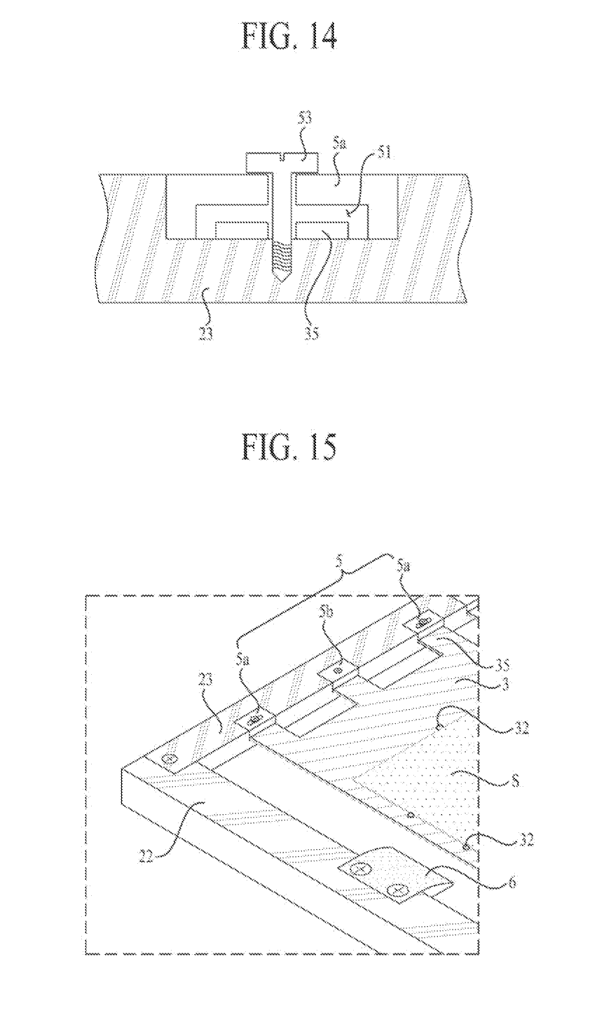

Referring to FIGS. 13 and 14, the mounting unit 5 may include a receiving portion 51 for receiving the fixing portion 35 therein. The mounting unit 5 including the receiving portion 51 is referred to as the first mounting unit 5. The receiving portion 51 is larger than the fixing portion 35. That is, the size of the receiving portion 51 is determined within a range enabling to receive the fixing portion 35 heated and expanded during the process of the substrate (S). That is, the receiving portion 51 is a predetermined space capable of receiving the fixing portion 35 therein.

The third frame member 23 is provided with a groove for the first mounting unit 5. The first mounting unit 5 is inserted into the groove, and is then connected with the third frame member 23. The fixing portion 35 is arranged between the third frame member 23 and the first mounting unit 5. When the third frame member 23 and the first mounting unit 5 are connected with each other, the fixing portion 35 is connected with and fixed to the third frame member 23 and the first mounting unit 5.

The space formed between the first mounting unit 5 and the third frame member 23 is the receiving portion 51 for receiving the fixing portion 35 therein. The receiving portion 51 is larger than the strap 3.

Referring to FIG. 15, the substrate tray 1 according to the present invention may include the plurality of mounting units 5 for mounting the plurality of straps 3 on the support frame 2. The mounting unit 5 is connected with the fixing portion 35 of the strap 3.

The strap 3 is diverged into the three fixing portions 35.

Among the plurality of fixing portions 35, the two fixing portions 35 being adjacent to the edge of the strap 3 are mounted by the above-described first mounting unit 5. A detailed description of the first mounting unit 5 will be omitted.

Meanwhile, the fixing portion 35, which is positioned in the center among the plurality of fixing portions 35, is connected by the second mounting unit 5, wherein the second mounting unit 5 is different from the first mounting unit 5. That is, the second mounting unit 5 is connected with the central portion in the second axis direction (Y-axis direction) of the strap 3.

In relation with the tension maintaining unit 4, the portion on which the second mounting unit 5 is mounted correctly fixes the strap 3, to thereby maintain the tension of the strap 3. That is, one end of the strap 3 is pulled by the tension maintaining unit 4, and the other end of the strap 3 is fixed by the second mounting unit 5, to thereby maintain the tension of the strap 3.

The second mounting unit 5 may include a restricting portion 52 for pressing and fixing the fixing portion 35 of the strap 3. That is, the restricting portion 52 is provided to restrict the movement of the fixing portion 35. If the second mounting unit 5 is inserted into and connected with the groove of the third frame member 23, the restricting portion 52 presses the fixing portion 35 so that the fixing portion 35 is stably connected with the third frame member 23 and the second mounting unit 5.

In the above description for the embodiments of the present invention, there are the plurality of second mounting units 5, but not necessarily. It is possible to provide one or more second mounting units 5.

According to the present invention, it is possible to omit the first mounting unit 5, and the fixing portion 35 is fixed by the use of second mounting unit 5.

Referring to FIG. 3, the substrate tray 1 according to the present invention may include a plurality of prominent pieces 6 for elevating the substrate tray 1. The plurality of prominent pieces 6 may be formed in the first frame member 21 and the second frame member 22.

Each of the first frame member 21 and the second frame member 22 may be provided with a connection groove 25 into which the prominent piece 6 is fixedly inserted. The connection groove 25 may be formed by removing the upper surface of the first frame member 21 and the second frame member 22.

The prominent piece 6 is inserted into the connection groove 25, and is connected with the first frame member 21 and the second frame member 22. The prominent piece 6, which is prominent toward the center of the substrate tray 1 with respect to the second axis direction (Y-axis direction), is connected with the first frame member 21 and the second frame member 22. The prominent piece 6 is inserted into the connection groove 25, and is connected with the connection groove 25 by the use of additionally-provided fastening member 62.

In the drawings, the number of prominent pieces 6 and connection members 25 provided in the first frame member 21 is two, and the number of prominent pieces 6 and connection members 25 provided in the second frame member 22 is two, to thereby provide four. However, the number of prominent pieces 6 and connection members 25 may be larger or smaller than the above-described number.

Hereinafter, the substrate processing apparatus according to the embodiment of the present invention will be described in detail with reference to the accompanying drawings.

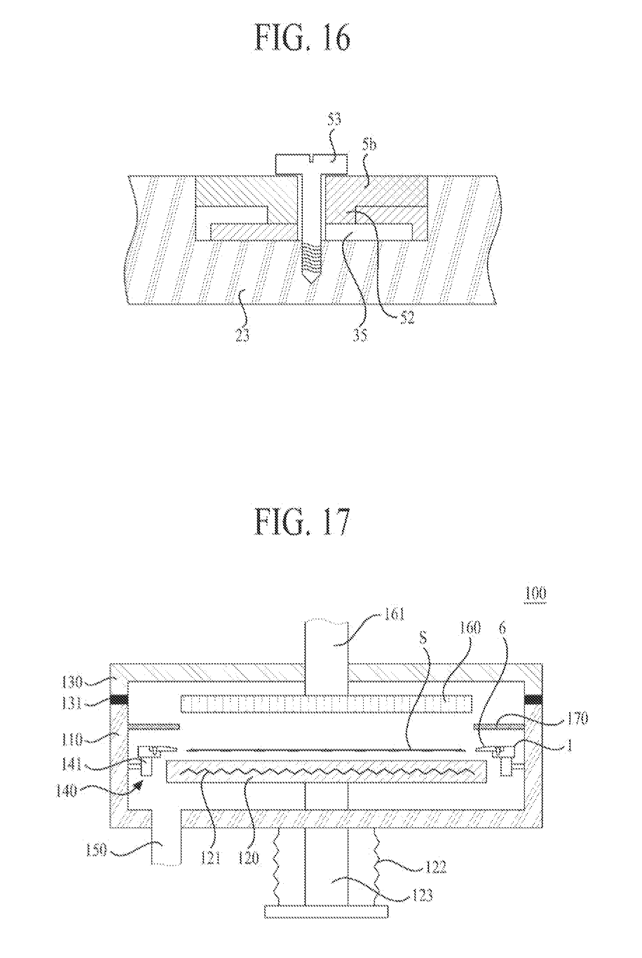

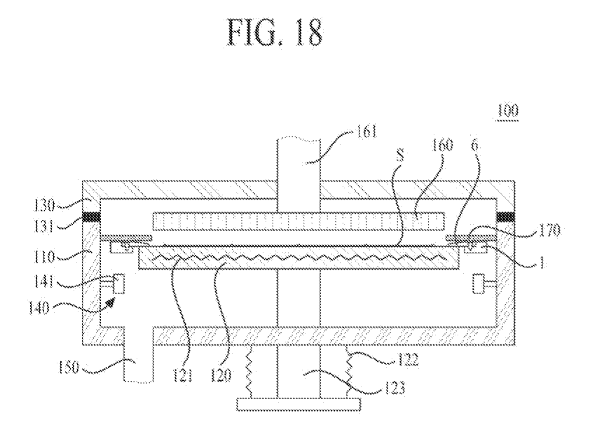

Referring to FIGS. 17 and 18, the substrate processing apparatus 100 according to the present invention may include a process chamber 110 and a susceptor 120. Also, the substrate processing apparatus 100 according to the present invention may further include a chamber lid 130, a tray transfer means 140, and a gas distribution means 160.

The process chamber 110 provides a process space for substrate processing, for example, thin film deposition process, etching process, cleaning process, and etc. The process chamber 110 may include a gate valve (not shown) which is provided to load the substrate tray 1 into the process space or to unload the substrate tray 1 from the process space, and an exhaust pipe 150 for discharging gas and byproducts from the process space.

The chamber lid 130 is provided on the process chamber 110, that is, the chamber lid 130 covers the process chamber 110, to thereby support the gas distribution means 160. Between the upper side of the process chamber 110 and the chamber lid 130, there is an insulator 315 so as to electrically insulate the chamber lid 130 and the process chamber 110 from each other.

The susceptor 120 is supported by an elevating axis 123 penetrating through the bottom surface of the process chamber 110. In this case, the elevating axis 123 is surrounded by a bellows 124. The substrate tray 1 supported by the tray transfer means 140 is elevated to the process position in accordance with the driving of elevating axis driving apparatus (not shown), as shown in FIG. 19, or the substrate tray 1 is placed onto a tray transfer roller 141 of the tray transfer means 140 according as the substrate tray 1 positioned at the process position is moved downward to the tray loading/unloading position, as shown in FIG. 18.

If the susceptor 120 is moved upward in accordance with the driving of elevating axis driving apparatus, the susceptor 120 upwardly moves the substrate tray 1 through the plurality of prominent pieces 119 provided in the substrate tray 1. In this case, each strap 3 of the substrate tray 1 is placed on the upper surface of the susceptor 120.

The susceptor 120 heats each substrate (S) loaded onto the substrate tray 1 to a temperature appropriate for the substrate processing. To this end, the susceptor 120 may further include a heating means 121 provided therein.

The heating means 121 heats the susceptor 120 to a predetermined temperature whereby the plurality of substrates (S) loaded onto the substrate tray 1 are heated to a temperature appropriate for the substrate processing. The heating means 121 may include a resistance heater, a hot wire heater, or a lamp heater. Accordingly, the plurality of substrates (S) align-loaded onto the substrate tray 1 are heated to the temperature appropriate for the substrate processing by the temperature of the susceptor 120.

The tray transfer means 140 is provided adjacent to the gate valve of the process chamber 110, to thereby load the substrate tray 1 to the process space or unload the substrate tray 1 from the process space. To this end, the tray transfer means 140 may include a plurality of driving rollers (not shown) for supporting the substrate tray 1 and transferring the substrate tray 1. Also, a tray supplying means according to another embodiment of the present invention may include a conveyor belt (not shown) for supporting and transferring the substrate tray 1, and a plurality of driving rollers (not shown) for rotating the conveyor belt (not shown).

The tray transfer means 140 may include a plurality of tray transfer rollers 141 provided at both sidewalls of the process chamber 110 corresponding to the gate valve prepared in the process chamber 110.

Each of the tray transfer rollers 141 supports the substrate tray 1 loaded into the process space through the gate valve in accordance with the driving of tray supplying apparatus, and loads the supported substrate tray 1 into the tray supplying apparatus, another process chamber or a load lock chamber in accordance with the driving of roller driving apparatus (not shown) when the substrate processing is completed.

The gas distribution means 160 which confronts the susceptor 120 is provided below the chamber lid 130, and is connected with a gas supply pipe 161 penetrating through the chamber lid 130. The gas distribution means 160 distributes gas supplied from an external gas supply means (not shown) (for example, process gas, cleaning gas, or source gas for deposition) onto the susceptor 120. To this end, the gas distribution means 160 may include a gas diffusion space (not shown) for diffusing the gas supplied from the gas supply pipe 161, and a plurality of gas distribution holes (not shown) being in communication with the gas diffusion space so as to uniformly distribute the gas onto the entire area of the susceptor 120.

Meanwhile, if the substrate processing apparatus carries out the substrate processing by the use of plasma formed in the process space, the gas distribution means 160 may be electrically connected with an externally-provided plasma power supply means (not shown), or may be electrically connected with the plasma power supply means (not shown) through the gas supply pipe 161. In this case, the gas distribution means 160 serves as a plasma electrode.

The substrate processing apparatus according to the present invention may further include a cover frame 170 provided at an inner sidewall of the process chamber 110 so as to cover the upper edge of the substrate tray 1.

The cover frame 170 covers the upper edge of the substrate tray 1 being elevated to the processing position, to thereby prevent arcking from occurring in the substrate tray 1 for the substrate processing. The cover frame 170 may be formed of an insulating material, for example, ceramic material or nonmetal material including ceramic material.

A substrate processing method using the substrate processing apparatus according to the present invention will be described as follows.

First, as shown in FIG. 17, the substrate tray 1 with the plurality of substrates (S) align-loaded onto the plurality of straps 3 is loaded into the inside of the process chamber 110, and is then placed onto the tray transfer roller 141 of the tray transfer means 140.

Then, as shown in FIG. 18, the susceptor 120 is elevated by driving the elevating axis driving apparatus, whereby the plurality of substrates (S) loaded onto the substrate tray 1 are positioned at the processing position.

During the process for elevating the susceptor 120 or after positioning each substrate (S) to the processing position, the heating means 121 provided inside the susceptor 120 is driven so as to heat the susceptor 120, whereby the plurality of substrates (S) loaded onto the substrate tray 1 are heated to the temperature appropriate for the substrate processing.

During the process for heating the substrate (S), each strap 3 of the substrate tray 1 may be expanded by the temperature of susceptor 120 or the temperature of process space, whereby the length of each strap 3 may be increased. Thus, the sliding bracket 41 may slide in the direction being away from the third frame member 23 in accordance with the elasticity of elastic member 42, whereby the connection portion 34 may be pulled in the direction from being away from the third frame member 23. Accordingly, the tension in each strap 3 is constantly maintained by the sliding of sliding bracket 133 in accordance with the elasticity of elastic member 42 so that it is possible to prevent each strap 3 from sagging by the thermal expansion of the strap 3, thereby preventing process defects.

Then, when the plurality of substrates (S) are positioned at the processing position, the gas is distributed onto each substrate (S) through the gas distribution means 160, thereby carrying out the substrate processing. The substrate processing may be the process for forming plasma in the space between the substrate (S) and the gas distribution means 160 by supplying the gas from the gas distribution means 160 and supplying plasma power, but not limited to the process for forming plasma. The substrate processing may be the deposition process, etching process or cleaning process.

After completing the substrate processing, the susceptor 120 is moved downward, whereby the substrate tray 1 placed onto the susceptor 120 is placed onto the tray transfer roller 141.

Then, the substrate tray 1 is unloaded from the process chamber 110 to the outside in accordance with the driving of tray transfer roller 141. In this case, each strap 3 of the substrate tray 1 unloaded from the process chamber 110 is shrinking by a surrounding temperature outside the process chamber 110, whereby the sliding bracket 41 connected with each strap 3 slides in the direction being adjacent to the third frame member 23 in accordance with thermal shrinkage in each strap 3 and compression of the elastic member 42.

According to the present invention, since the plurality of substrates (S) are supported by the use of plural straps 3, the large-sized substrate tray 1 is realized with easiness by increasing the number of straps 3, whereby it is possible to carry out the substrate processing for the increased number of substrates (S) at once, thereby improving the yield.

Also, the plurality of substrates (S) are supported by the use of plural straps 3, and the tension of the strap 3 is constantly maintained by the elastic member of the tension maintaining member, whereby it is possible to prevent each strap 3 from sagging, thereby preventing the process defects such as pick-up failure of the substrate (S) and non-uniformity of process.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A substrate tray comprising:
a plurality of straps for supporting a plurality of substrates arranged in a first axis direction; and
a support frame connected with the straps in a second axis direction being perpendicular to the first axis direction,
wherein a length in each of the straps is larger than a length of the substrate with respect to the second axis direction.

2. The substrate tray according to claim 1, wherein the straps are provided at fixed intervals in the second axis direction, and are connected with the support frame.

3. The substrate tray according to claim 1, further comprising a transmitting portion penetrating through the strap so as to transmit heat from a lower side of the strap to the substrate supported on the strap.

4. The substrate tray according to claim 3, wherein the transmitting portion is formed in a predetermined size, which is relatively smaller than a size of the substrate, so as to stably support the substrate on the strap, and the plurality of transmitting portions are provided at fixed intervals in the strap.

5. The substrate tray according to claim 1, wherein the strap includes a support surface for supporting the substrate, and a plurality of protrusions protruding from the support surface, and the plurality of protrusions are brought into contact with each side of the substrate supported on the support surface.

6. The substrate tray according to claim 1, wherein the straps includes a support surface for supporting the respective substrates, and a plurality of protrusions protruding from the support surface, and the plurality of protrusions are provided at a predetermined interval from each side of the substrate supported on the support surface.

7. The substrate tray according to claim 5, wherein the support surface and the protrusion are formed as one body.

8. The substrate tray according to claim 5, wherein the protrusion is formed by curving the support surface.

9. The substrate tray according to claim 1, further comprising a plurality of tension maintaining units for maintaining a tension in each of the straps,
wherein each of the straps includes a connection portion connected with the tension maintaining unit, and
wherein each tension maintaining unit includes a sliding bracket connected with the connection portion, and an elastic member positioned between the sliding bracket and the support frame.

10. The substrate tray according to claim 9, wherein each of the straps includes the plurality of connection portions, and each of the sliding brackets is connected with the plurality of connection portions.

11. The substrate tray according to claim 9, further comprising at least one mounting unit for mounting the respective straps on the support frame,
wherein each strap includes a support surface for supporting the substrate, and a fixing portion connected with the mounting unit, and the connection portion and the fixing portion are provided in opposite sides with respect to the support surface.

12. The substrate tray according to claim 1, further comprising at least one mounting unit for mounting the respective straps on the support frame,
wherein each strap includes a fixing portion connected with the mounting unit, and the mounting unit includes a receiving portion for receiving the fixing portion therein, wherein a size of the receiving portion is larger than a size of the fixing portion.

13. The substrate tray according to claim 1, further comprising at least one mounting unit for mounting the respective straps on the support frame,
wherein each strap includes a fixing portion connected with the mounting unit, and the mounting unit includes a restricting portion for restricting the movement of fixing portion.

14. A substrate tray comprising:
a plurality of straps for supporting a plurality of substrates arranged in a first axis direction; and
a support frame connected with the plurality of straps in a second axis direction being perpendicular to the first axis direction,
wherein a length of each of the straps is the same as a length of the substrate with respect to the second axis direction.

15. A substrate processing apparatus comprising:
a process chamber for providing a process space;
a susceptor movably provided in the process chamber; and
a substrate tray loaded into the process space and supported by the susceptor,
wherein the substrate tray includes:
a plurality of straps for supporting a plurality of substrates arranged in a first axis direction; and
a support frame connected with the plurality of straps in a second axis direction being perpendicular to the first axis direction,
wherein a length of each of the straps is larger than a length of the substrate with respect to the second axis direction.

16. A substrate processing apparatus comprising:
a process chamber for providing a process space;
a susceptor movably provided in the process chamber; and
a substrate tray loaded into the process space and supported by the susceptor,
wherein the substrate tray includes:
a plurality of straps for supporting a plurality of substrates arranged in a first axis direction; and
a support frame connected with the plurality of straps in a second axis direction being perpendicular to the first axis direction,
wherein a length of each of the straps is the same as a length of the substrate with respect to the second axis direction.

17. The substrate processing apparatus according to claim 15, wherein the substrate tray further includes a plurality of prominent pieces protruding toward the straps in the support frame, and the susceptor moves up and down the plurality of prominent pieces so as to move up and down the substrate tray.

18. The substrate processing apparatus according to claim 15, wherein the substrate tray further includes a transmitting portion penetrating the strap so as to transmit heat emitted from the susceptor to the substrate supported on the strap.

19. The substrate processing apparatus according to claim 16, wherein the substrate tray further includes a plurality of prominent pieces protruding toward the straps in the support frame, and the susceptor moves up and down the plurality of prominent pieces so as to move up and down the substrate tray.

20. The substrate processing apparatus according to claim 16, wherein the substrate tray further includes a transmitting portion penetrating the strap so as to transmit heat emitted from the susceptor to the substrate supported on the strap.
